(19) United States
(12) Patent Application Publication
(10) Pub. No.: US 2024/0412985 A1
(43) Pub. Date: Dec. 12, 2024

(54) DEDICATED SULFURIC-PEROXIDE PROCESS MODULE FOR POST-CMP CLEANING PLATFORMS

(71) Applicant: Applied Materials, Inc., Santa Clara, CA (US)

(72) Inventors: Clinton SAKATA, San Jose, CA (US); Ricardo MARTINEZ, Manteca, CA (US); Robert DUES, Austin, TX (US); Shih-Yu LIU, Santa Clara, CA (US); Tarun Kumar ABICHANDANI, Sunnyvale, CA (US); Brian K. KIRKPATRICK, Sunnyvale, CA (US); Jagan RANGARAJAN, San Jose, CA (US); Adrian S. BLANK, Gilroy, CA (US); Edward GOLUBOVSKY, San Jose, CA (US); Justin H. WONG, Pleasanton, CA (US)

(21) Appl. No.: 18/731,436

(22) Filed: Jun. 3, 2024

Related U.S. Application Data
(60) Provisional application No. 63/506,429, filed on Jun. 6, 2023.

(51) Int. Cl. H01L 21/67; B65G 47/90; H01L 21/687

(52) U.S. Cl. CPC H01L 21/67057; B65G 47/907; H01L 21/67219; H01L 21/68707

(57) ABSTRACT

A substrate cleaning system to remove particulates from multiple substrates includes a cleaning tank for applying a cleaning liquid to substrates, a rinse tank for applying a rinsing liquid to substrates, and a robot system. The cleaning tank includes a stationary lid, an input lid, and an output lid. The input and output lids allow a substrate carrier designed to carry an individual substrate to access an inner volume of the cleaning tank for processing. A transport system moves the substrate in the substrate carrier through the inner volume of the cleaning tank by creating a series of gaps between substrates to allow proper processing. The robot system transports substrates through the input and output lids of the cleaning tank, and transports substrates into the rinse tank.

### CROSS-REFERENCE TO RELATED APPLICATION(S)

This application claims the benefit of and priority to U.S. Provisional Application 63/506,429 filed on Jun. 6, 2023, which is assigned to the assignee hereof and hereby expressly incorporated by reference herein in its entirety as if fully set forth below and for all applicable purposes.

### BACKGROUND

### Field

Embodiments of the presently disclosed subject matter generally relate to apparatus, system, and methods for in-line post polish cleaning of substrates, such as semiconductor substrates.

### Description of the Related Art

An integrated circuit is typically formed on a substrate (e.g., a semiconductor wafer) by the sequential deposition of conductive, semiconductive, or insulative layers on the substrate, and by the subsequent processing of the layers.

One fabrication step involves depositing a filler layer over a non-planar surface disposed on the substrate and planarizing the filler layer until the non-planar surface is exposed. For example, a conductive filler layer can be deposited on a patterned insulative layer disposed on the substrate to fill the trenches or holes in the insulative layer. The filler layer is then polished until the raised pattern of the insulative layer is exposed.

Chemical mechanical polishing (CMP) is one accepted method of planarization known in the art. This planarization method typically requires that the substrate be mounted on a carrier head. The exposed surface of the substrate is placed against a rotating polishing pad. The carrier head provides a controllable load on the substrate to push it against the polishing pad. For example, the carrier head may provide a specified pressure on the backside of the substrate to push it against the polishing pad. A polishing liquid, such as a slurry with abrasive particles, is supplied to the surface of the polishing pad. For example, cerium-based slurries, such as slurries containing cerium oxide, can be used in the polishing of a semiconductor or insulating thin layer in CMP.

The slurry of abrasive particles can include cerium oxide particulates and other additives which contribute to the polishing process. The benefits allow the substrates to be polished with stability without generating scratches. To remove these particulates, the substrates can be subjected to a cleaning process that can include the use of harsh oxidizing solvents. For example, a mixture of sulfuric acid and hydrogen peroxide (e.g., sulfuric peroxide mixture (SPM)) can be used in the removal or dissolution of cerium oxide particulates from the surfaces of a substrate after polishing. SPM cleaning can be performed in a parallel separated mode in which each substrate is placed in a bath in a separate tank. Typically, the SPM cleaning process is performed in a separate wet bench apparatus in which substrates are inbound in a dry state after the CMP polishing. It is performed to enhance other methods of post-CMP cleaning in which cerium oxide particulates are not sufficiently removed.

The substrates are generally processed through an SPM cleaning tank in batches. This method is not compatible with CMP polishing platforms based on single-substrate processing since the cleaning tank requires its lid to open a significant percentage of time substrates are being processed due to the frequency of substrates being inserted into the SPM cleaning tank due to the platform's high substrate throughput. When the lid of the SPM tank opens, steam and sulfuric vapors escape causing a change in temperature, bath concentration, as well as increasing the risk of cross contamination between cleaning processes. In addition, during single-substrate processing each substrate is exposed for different times due to robotic transfer sequencing activities, which poses additional control challenges. Based on the above, there is a need for improvement in the method of cleaning substrates and to allow the integration of an SPM process to work within a single-substrate processing platform.

### SUMMARY

Embodiments described herein generally relate to systems and methods used for apparatus, system, and methods for in-line post polish cleaning of substrates, such as semiconductor substrates. More particularly, embodiments herein provide for systems and methods using cleaning modules and a cleaning tank to allow for more efficient substrate cleaning.

In an embodiment, a system for cleaning a substrate is provided. The system includes an input tank having an input tank opening that is configured to receive a substrate oriented in a vertical orientation, a cleaning tank oriented substantially parallel to the input tank, and the cleaning tank having a stationary lid. At least one input lid assembly is adjacent to a first side of the stationary lid and configured to open to an input side of the cleaning tank. At least one output lid assembly is adjacent to a second side of the stationary lid and configured to open to an output side of the cleaning tank, where the stationary lid, input lid assembly, and the output lid assembly covers a top surface of the cleaning tank. A transport system is configured to transport the substrate from the input side of the cleaning tank to the output side of the cleaning tank. Further, a soak tank is included that has an opening adjacent to the output side of the cleaning tank and configured to hold a plurality of substrates. A plurality of rinse tanks adjacent to the soak tank are each configured to hold a single substrate. An output tank is adjacent to the plurality of rinse tanks, the output tank having a transport system to advance a substrate through the output tank. The system also includes a plurality of transfer robot arms configured to transfer the substrate between the input tank, the cleaning tank, the soak tank, the plurality of rinse tanks, and the output tank.

In another embodiment, a system for cleaning a substrate is provided. The system includes an input tank, a cleaning tank configured to contain a cleaning solution for applying to the substrate, the cleaning tank having a top surface and an outer surface adjacent to the top surface, the top surface and the outer surface defining an inner volume, and the outer surface having an upper portion and a lower portion. A first transport system is connected to the upper portion of the cleaning tank, the lower portion of the cleaning tank, or a combination thereof. The first transport system is configured to transport a substrate carrier containing the substrate. The system includes a stationary lid covering a majority of the top surface of the cleaning tank, at least one input lid assembly adjacent to a first side of the stationary lid, and at least one output lid assembly adjacent to a second side of the stationary lid, wherein the at least one input lid assembly, the stationary lid, and the at least one output lid assembly cover an entirety of the top surface. The system also includes a rinse tank, wherein the rinse tank includes a second transport system configured to transport the substrate carrier containing the substrate through the rinse tank, an output tank. Further, the system includes a robot system having a plurality of robot arms configured to transfer the substrate carrier between the input tank, the cleaning tank, the rinse tank, and the output tank.

In yet another embodiment, a system for cleaning a substrate is provided. The system includes a polishing station, a cleaning unit having at least one horizontal pre-clean module, at least one vertical cleaning module, and at least one drying module, an input tank, a cleaning tank having a stationary lid, at least one input lid assembly adjacent to a first side of the stationary lid configured to open to an input side of the cleaning tank, at least one output lid assembly adjacent to a second side of the stationary lid configured to open to an output side of the cleaning tank, wherein the stationary lid, input lid assembly, and the output lid assembly covers a top surface of the cleaning tank, and a transport system configured to transport the substrate from the input side of the cleaning tank to the output side of the cleaning tank, a soak tank, a plurality of rinse tanks, an output tank, a substrate handler configured to transport a substrate between the polishing station, the cleaning unit, the input tank, and the output tank, a first transfer robot arm assembly, a second transfer robot arm assembly, and a third transfer robot arm assembly configured to transfer the substrate between the input tank, the cleaning tank, the soak tank, the plurality of rinse tanks, and the output tank, and a controller having a memory and processor. The controller is configured to insert the substrate into the cleaning tank using the first transfer robot arm, transport the substrate through a queue along the cleaning tank using the transport system, and removing the substrate from the cleaning tank using the second transfer robot arm assembly after the substrate reaches an end of the queue.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic top view of an exemplary chemical mechanical polishing (CMP) processing system, according to one or more embodiments.

FIG. 1B is a schematic side view of the CMP processing system, shown from the perspective of section line B-B of FIG. 1A, according to one or more embodiments.

FIG. 1C is a schematic side view of the CMP processing system, shown from the perspective of section line C-C of FIG. 1A, according to one or more embodiments.

FIG. 1D is an isometric view of portions of the cleaning unit of FIG. 1C, according to one or more embodiments.

FIG. 2A is a schematic side view of a sulfuric peroxide mixture (SPM) module of the CMP processing system of FIGS. 1A-1D, according to one or more embodiments.

FIG. 2B is a schematic front view of a portion of the SPM module of FIG. 2A, according to one or more embodiments.

FIG. 3 is a schematic side view of an SPM module of the CMP processing system of FIGS. 1A-1D, according to one or more embodiments.

FIGS. 4A-4F are schematic diagrams of a walking beam system, according to one or more embodiments.

FIG. 5 is a schematic front view of an SPM module of the CMP processing system of FIGS. 1A-1D, according to one or more embodiments.

FIG. 6 is a schematic front view of an SPM module of the CMP processing system of FIGS. 1A-1D, according to one or more embodiments.

FIGS. 7A-7F are schematic diagrams of a walking beam system according to embodiments discussed herein.

FIGS. 8A-8F are schematic diagrams of a running beam system according to embodiments discussed herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Cleaning process sequences that include a sulfuric peroxide mixture (SPM) cleaning process includes many hardware and cleaning process challenges. SPM cleaning in some cases can be performed in a parallel separated mode in which each substrate is placed in a bath in a separate processing chamber, or tank. Although this permits parallel processing of multiple substrates, the use of separate tanks can increase the use of the processing chemistry, e.g., the sulfuric acid and hydrogen peroxide. Further, the SPM cleaning chemistry may not be reusable, e.g., new chemistry may be needed for each substrate, which can be wasteful and lead to a significant operating expense.

Moreover, the time required for performing an SPM cleaning process can be fairly large relative to the polishing time, e.g., by a factor of 10 or more. Thus, in order to match the throughput of the polishing system so that SPM process is not the gating process that limits the cleaning system throughput, a large number of substrates would need to be processed in parallel by SPM. However, including multiple SPM tanks with each chamber processing a single substrate might not be feasible, due to cost, available footprint in the clean room, or chemistry expense.

An approach that addresses one or more of the issues described above includes an SPM processing system in which multiple substrates are processed in the same tank while sharing and maintaining the chemistry of the SPM. Additionally, embodiments of the disclosure provided herein include a SPM cleaning process that utilizes an SPM tank and a series of processing chambers or tanks that are adapted to prepare a substrate for the SPM cleaning process and/or prepare a substrate for subsequent cleaning processes after the SPM cleaning process has been performed on the substrate.

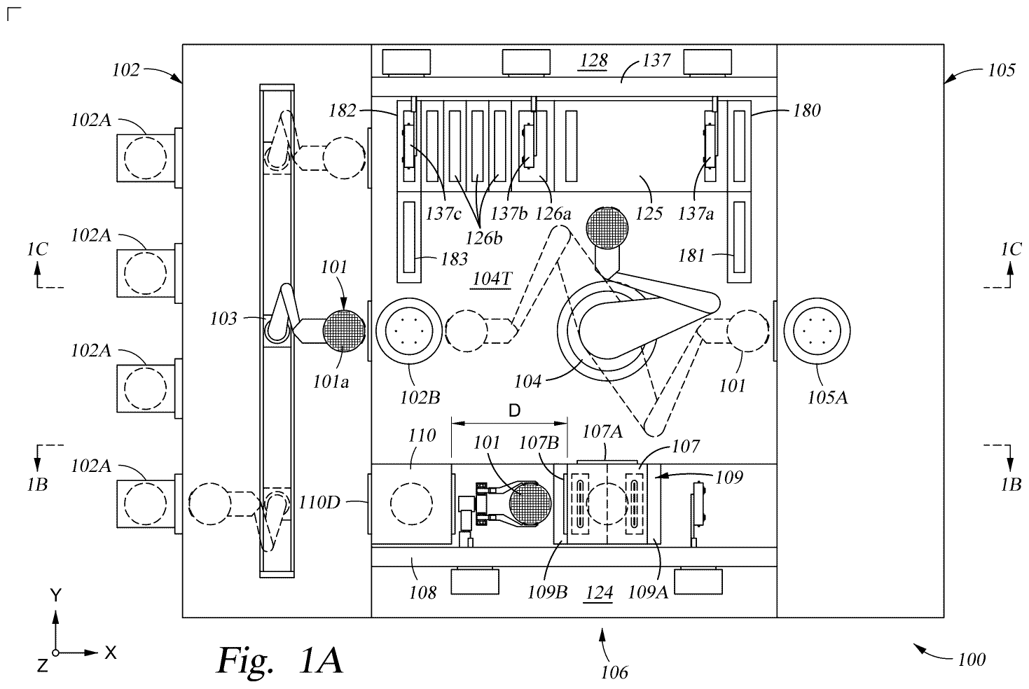

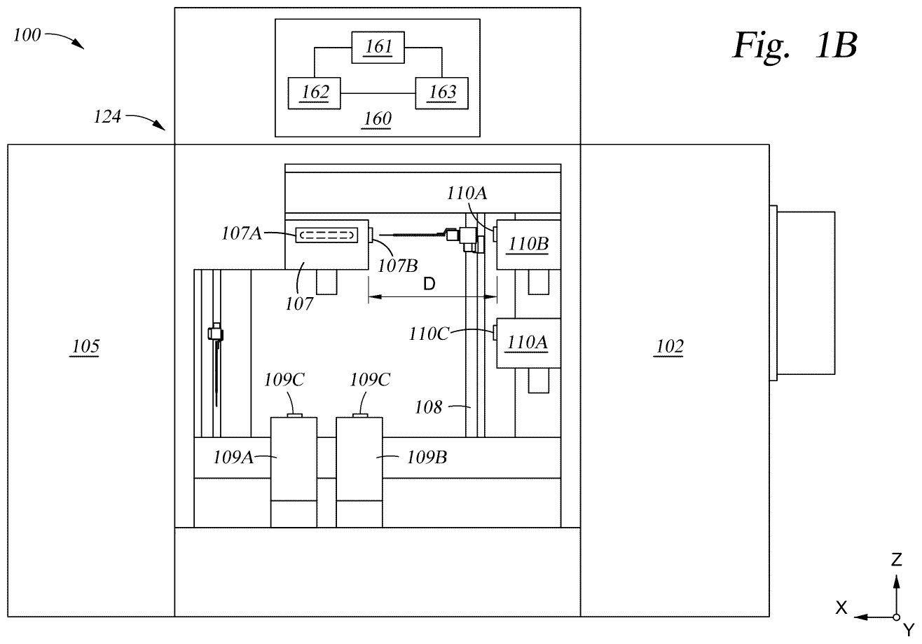

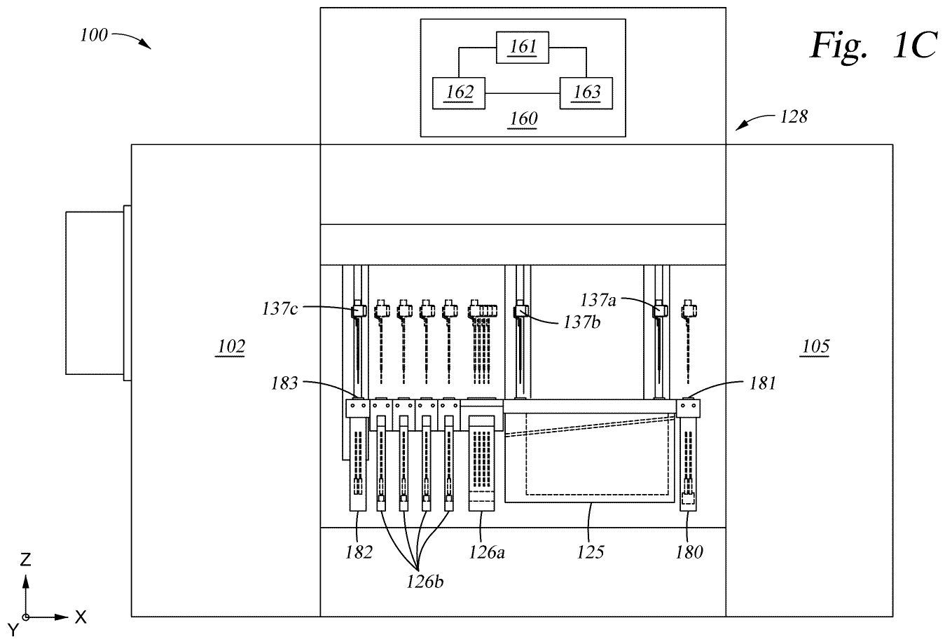

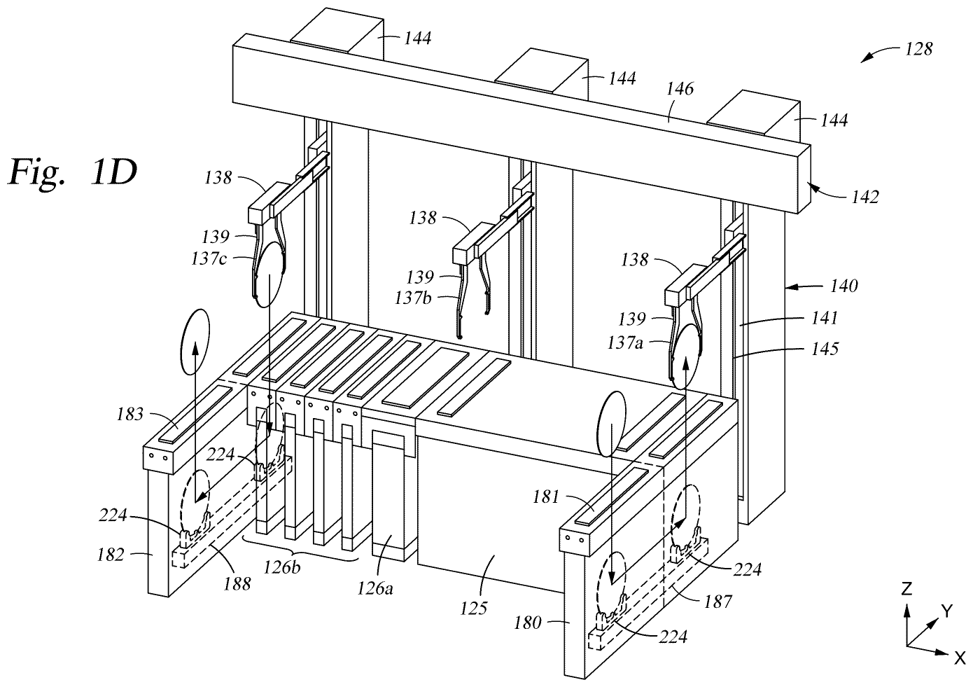

FIG. 1A is a schematic top view of an exemplary chemical mechanical polishing (CMP) processing system 100 described herein, according to one or more embodiments. FIG. 1B is a schematic side view of the CMP processing system 100, shown from the perspective of section line B-B, according to one or more embodiments. FIG. 1C is a schematic side view of the CMP processing system 100, shown from the perspective of section line C-C in FIG. 1A, according to one or more embodiments. FIG. 1D is an isometric view of portions of the cleaning unit 128 of FIG. 1C, according to one or more embodiments. While the disclosure provided herein primarily discusses various embodiments that can be used in conjunction with a CMP device, such as a polishing station 105, this configuration is not intended to be limiting as to the scope of the disclosure provided herein.

In the figures, certain parts of the housing and certain other internal and external components are omitted to more clearly show aspects of the CMP processing system 100. Here, the CMP processing system 100 is connected to a factory interface 102. The factory interface 102 may include one or more loading stations 102A. The loading stations 102A may be, for example, FOUPs or cassettes. Each loading station 102A may include one or more substrates 101 for CMP processing in the CMP processing system 100.

The CMP processing system 100 may include a polishing station 105, a first substrate handler 103 of the factory interface 102 and a cleaning system 106 that includes a second substrate handler 104. The first substrate handler 103 is positioned to transfer a substrate 101 to and from one or more of the loading stations 102A. For example, the first substrate handler 103 transfers a substrate 101 from a loading station 102A to the cleaning system 106, e.g., to a cleaner pass-through 102B, where the substrate 101 can be picked up by the second substrate handler 104. As another example, the first substrate handler 103 transfers a substrate 101 from the cleaning system 106, e.g., from the cleaner pass-through 102B, to the loading station 102A.

Generally, a substrate 101 that is initially positioned in a loading station 102A has been subject to a prior manufacturing process or processes-such as, for example, wafering, lithography, etching, or deposition processes-on a processing surface 101a thereof. The first substrate handler 103 transfers the substrate to and from the loading station 102A with the processing surface 101a facing up.

The second substrate handler 104 may be, for example, a cleaner wet robot. The second substrate handler 104 is positioned to transfer a substrate 101 to and from the polishing station 105 with the processing surface 101a facing up. For example, the second substrate handler 104 receives a substrate 101 from the cleaner pass-through 102B or the first substrate handler 103 and then transfers the substrate 101 to a transfer station 105A within the polishing station 105. As another example, the second substrate handler 104 retrieves a substrate 101 from the transfer station 105A within the polishing station 105 and then transfers the substrate 101 to a first cleaning module 107 in the cleaning system 106.

The polishing station 105 is a substrate polishing system that may include a plurality of polishing stations (not shown). The polishing station 105 includes one or more polishing assemblies that are used to polish a substrate 101 received from the second substrate handler 104 using one or more CMP processes. Typically, each of the one or more polishing assemblies include the use of a polishing platen (not shown) and polishing head (not shown), which is configured to urge the substrate 101 against a polishing pad (not shown) disposed on the polishing platen. Residual abrasive particles or liquids such as acidic or basic chemicals may remain on the substrate 101 after undergoing CMP processing in the polishing station 105. Accordingly, the cleaning system 106 is positioned between the polishing station 105 and the factory interface 102 in order to clean the substrate 101 prior to returning the substrate 101 to the loading station 102A.

As shown in FIG. 1A, the cleaning system 106 may be comprised of two cleaning units, a first cleaning unit 124 and a second cleaning unit 128, disposed in parallel to one another on opposite sides of the second substrate handler 104. The first cleaning unit 124 and the second cleaning unit 128 include a plurality of cleaning modules, such as one or more first cleaning modules, one or more second cleaning modules and one or more third cleaning modules, as discussed below. FIG. 1B is a side view of the first cleaning unit 124. FIG. 1C is a side view of the second cleaning unit 128 and FIG. 1D is a top isometric view of the second cleaning unit 128, with a housing (and other internal and external components) omitted for clarity.

As shown in FIG. 1A, the first cleaning unit 124 may be separated from the second cleaning unit 128 by a robot tunnel 104T in which the second substrate handler 104 is positioned. In some embodiments, the first substrate handler 103 transfers the substrate 101 from the loading station 102A to the polishing station 105 for processing. After polishing the substrate in the polishing station 105, the second substrate handler 104 transfers the substrate 101 from the polishing station 105 to the second cleaning unit 128. Alternatively, the second substrate handler 104 may transfer the substrate 101 from the polishing station 105 to one or more cleaning units in the first cleaning unit 124 and then to the second cleaning unit 128. In one example, the substrate 101 may be transferred from the first cleaning unit 124 to the second cleaning unit 128 after an initial cleaning of the substrate in the first cleaning unit 124, e.g., after horizontal pre-cleaning, then after cleaning in the second cleaning unit 128 then back to the first cleaning unit 124 for further processing, e.g., brushing or drying. After the second cleaning unit 128 processes the substrate, the second substrate handler 104 may transfer the substrate 101 to the first cleaning unit 124 for processing before transferring the substrate 101 to the factory interface 102.

The first cleaning unit 124 may include the first cleaning module 107, a third substrate handler 108, a second cleaning module 109, and a third cleaning module 110. In some embodiments, the first cleaning module 107, while not intending to be limiting as to the scope of the disclosure provided herein, is often referred to herein as the horizontal pre-cleaning (HPC) module 107. In some embodiments, the second cleaning module 109, while not intending to be limiting as to the scope of the disclosure provided herein is often referred to herein as the vertical cleaning module 109. In some embodiments, the third cleaning module 110, while not intending to be limiting as to the scope of the disclosure provided herein, is often referred to herein as the drying or integrated clean dry (ICD) module 110. In some embodiments, the vertical cleaning module 109 may be provided as a first vertical cleaning module 109A and a second vertical cleaning module 109B. In some embodiments, the ICD module 110 may be provided as a first ICD module 110A and a second ICD module 110B. In some embodiments, as illustrate in FIG. 1A, the third substrate handler 108 within the cleaning unit 124 is positioned such that it is at an external edge of the cleaning unit 124 of the CMP processing system 100. In this configuration, the substrate handler 108 is positioned on an external side of the first, second, and third cleaning modules (107, 108, 110) that is opposite to an internal side of the first, second, and third cleaning modules (107, 108, 110) that faces the robot tunnel 104T and the second substrate handler 104 of the CMP processing system 100.

The HPC module 107 is configured to process a substrate 101 disposed in a substantially horizontal orientation, e.g., in the X-Y plane, with the processing surface 101a facing up. In some embodiments, the cleaning unit 124 includes two vertical cleaning modules 109A, 109B configured to process a substrate 101 disposed in a substantially vertical orientation, e.g., in the Z-Y plane, with the processing surface 101a facing the factory interface 102.

Referring to FIGS. 1A and 1B, the HPC module 107 receives a polished substrate 101 from the second substrate handler 104 through a first door 107A formed in a first side panel of the HPC module 107. The first door 107A may be, for example, a slit valve that is configured to isolate an interior region of the HPC module 107 from the exterior region of the HPC module 107. The substrate 101 is received in a horizontal orientation by the HPC module 107 for positioning on a horizontally disposed substrate support surface therein. The HPC module 107 then performs a pre-clean process, such as a buffing process, on the substrate 101 before the substrate 101 is transferred therefrom using the third substrate handler 108, which is also sometimes referred to herein as the third substrate handling device 108. In some embodiments, the buffing process includes delivering a cleaning fluid to a surface of the substrate and sweeping a buffing pad across a surface of the substrate 101 that is positioned on the horizontally disposed substrate support surface to remove left over slurry, scratches and other imperfections found on the surface of the substrate. The buffing pad may include a material such as a polyurethane, acrylate or other polymeric material.

Still referring to FIGS. 1A and 1B, the third substrate handler 108 transfers the substrate 101 from the HPC module 107 via a second door 107B of the HPC module 107. The second door 107B may be, for example, a slit valve. The substrate 101 is still in a horizontal orientation, e.g., oriented in the X-Y plane, as it is removed from the HPC module 107. After the substrate 101 is transferred from the HPC module 107, the third substrate handler 108 manipulates the substrate 101 to a vertical orientation, e.g., orientated in the Y-Z plane and the processing surface 101a facing the factory interface 102 for further processing in the vertical cleaning modules 109A, 109B of the cleaning system 106. For example, after the substrate 101 is transferred from the HPC module 107, the third substrate handler 108 may rotate the substrate 101 about the Y-axis by 90 degrees to change the orientation to the vertical position, and also rotate the substrate about the Z-axis by 180 degrees so that the processing surface 101a faces the factory interface 102. The Y-axis rotation and Z-axis rotation may be completed serially or with overlapping time intervals.

After manipulating the substrate 101 so that the processing surface 101a faces the factory interface 102, the third substrate handler 108 transfers the substrate 101 to the vertical cleaning module 109A through a door 109C (FIG. 1B). The transferring process may include the movement of the third substrate handler 108 in at least one direction, such as the X-direction. The door 109C may be, for example, a slit valve. The cleaning unit 124 may include two vertical cleaning modules 109A, 109B. The two vertical cleaning modules 109A, 109B may be arranged linearly, e.g., in the X direction, in the cleaning unit 124. The two vertical cleaning modules 109A, 109B may also be arranged substantially below the HPC module 107, e.g., in the Z direction, in the cleaning unit 124. Such an arrangement of the vertical cleaning modules 109A, 109B below the HPC module 107 may provide for a reduced footprint of the overall cleaning system 106 and also help to reduce the transfer time between these modules to improve throughput and importantly reduce a wet substrate's ability to dry and reduce the substrate's air exposure time between cleaning steps.

In some embodiments, the vertical cleaning modules 109A, 109B may be any one or combination of contact and non-contact cleaning systems for removing polishing byproducts from the surfaces of a substrate, e.g., spray boxes or scrubber brush boxes.

Referring to FIGS. 1A, 1C, and 1D, the cleaning unit 128 may include an input tank 180, a cleaning tank 125, a soak tank 126a, one or more rinse tanks 126b, and an output tank 182. The input tank 180 may also include an input shuttle opening 181 that is positioned at one end of the cleaning unit 128 to receive one or more substrates 101. When a substrate 101 is placed on a holder 224 of a substrate input shuttle 187 disposed below the input shuttle opening 181, the substrate input shuttle 187 then transfers the substrate into a position adjacent to the cleaning tank 125. Similarly, a substrate 101 can be placed on a holder 224 of an output shuttle 188 that is positioned in the output tank 182, and then transferred from a position within the output tank 182 that is adjacent to one or more rinse tanks 126b to a position that is below an output shuttle opening 183, which is positioned at an opposite end of the cleaning unit 128 from the input shuttle opening 181. The cleaning unit 128 may also include a fourth substrate handler 137 that includes one or more dedicated transfer robot arm assemblies 137a, 137b, 137c.

Specifically, the one or more dedicated transfer robot arm assemblies 137a, 137b, 137c each include a gripping actuator 138 to permit a pair of blades 139 on each assembly to open and close around the edge of a substrate 101. As best seen in FIG. 1D, each blade assembly is provided with a vertical actuator 141 disposed within a vertical actuator assembly 140 and a horizontal actuator assembly 142 for moving the transfer robot arm assemblies 137a, 137b, 137c to various horizontal and vertical locations and positions within the cleaning unit 128. As illustrated in FIG. 1D, each of the transfer robot arm assemblies 137a, 137b, 137c are coupled to a translatable portion of a vertical rail 145 (e.g., linear guide, linear ball slide, etc.) that is aligned in a vertical direction (i.e., Z-direction). Each of the rails 145 are disposed within a vertical actuator assembly 140, respectively, that are each movable along a horizontal rail 146 (e.g., linear guide, linear ball slide, etc.) within the horizontal actuator assembly 142 by use of a horizontal actuator 144 that is adapted to position the respective transfer robot arm assemblies 137a, 137b, 137c, in a horizontal direction (i.e., X-direction). In some embodiments, the horizontal actuators 144 and vertical actuators 141 may each include a linear actuator or motorized ball screw actuator assemblies that are configured to drive and position the respective components by use of commands from a system controller 160.

In some embodiments, the cleaning tank 125 may contain a substrate cleaning solution. Preferably, the cleaning tank 125 contains a mixture of sulfuric acid and hydrogen peroxide. Alternatively, the cleaning tank 125 may contain a mixture of sulfuric acid and ozone gas. The ozone gas may be added to the sulfuric acid or recirculated chemistry below a bottom dispersion plate or prior to the mixture entering the cleaning tank 125, for example in a specialty mixing location (not shown). In some embodiments, the soak tank 126a may be a post-SPM grouped soak tank configured to soak a plurality of substrates 101 after processing a substrate in a sulfuric acid and hydrogen peroxide mixture (SPM) disposed within the cleaning tank 125. The soak tank 126a can be configured as a grouped or batch substrate processing soak tank that is used to gradually decrease the temperature of the SPM processed substrates to prevent cracking or other structural damage to the substrates 101 during a subsequent rinsing processes performed in other downstream rinse tanks. The rinse tank 126b may include a plurality of quick dump rinse (QDR) tanks to effectively rinse and decontaminate each substrate 101 prior to exit through the output tank 182.

In embodiments herein, operation of the CMP processing system 100, including the fourth substrate handler 137, is directed by a system controller 160 (FIGS. 1B and 1C). The system controller 160 includes a programmable central processing unit (CPU) 161 which is operable with a memory 162 (e.g., non-volatile memory) and support circuits 163. The support circuits 163 are conventionally coupled to the CPU 161 and comprise cache, clock circuits, input/output subsystems, power supplies, and the like, and combinations thereof coupled to the various components of the CMP processing system 100, to facilitate control thereof. The CPU 161 is one of any form of general purpose computer processor used in an industrial setting, such as a programmable logic controller (PLC), for controlling various components and sub-processors of the processing system. The memory 162, coupled to the CPU 161, is non-transitory and is typically one or more of readily available memories such as random access memory (RAM), read only memory (ROM), floppy disk drive, hard disk, or any other form of digital storage, local or remote.

Typically, the memory 162 is in the form of a non-transitory computer-readable storage media containing instructions (e.g., non-volatile memory), which when executed by the CPU 161, facilitates the operation of the CMP processing system 100. The instructions in the memory 162 are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

Illustrative non-transitory computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory devices, e.g., solid state drives (SSD) on which information may be permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the substrate processing or handling methods set forth herein are performed by a combination of software routines, ASIC(s), FPGAs and, or, other types of hardware implementations. One or more system controllers 160 may be used with one or any combination of the various modular polishing systems described herein or with the individual polishing modules thereof.

The system controller 160 controls activities and operating parameters of the automated components found in the CMP processing system 100. In general, the bulk of the movement of a substrate through the processing system is performed using the various automated devices disclosed herein by use of commands sent by the system controller 160. In some embodiments, the system controller 160 is a general use computer that is used to control one or more components found in the CMP processing system 100. The system controller 160 is generally designed to facilitate the control and automation of one or more of the processing sequences disclosed herein and by use of the CPU 161, memory 162, and support circuits (or I/O) 163. Software instructions and data can be coded and stored within the memory (e.g., non-transitory computer readable medium) for instructing the CPU 161. A program (or computer instructions) readable by the processing unit within the system controller determines which tasks are performable in the processing system. For example, the non-transitory computer readable medium includes a program which when executed by the processing unit are configured to perform one or more of the methods described herein. Preferably, the program includes code to perform tasks relating to monitoring, execution and control of the movement, support, or positioning of a substrate along with the various process recipe tasks and various cleaning module process recipe steps being performed.

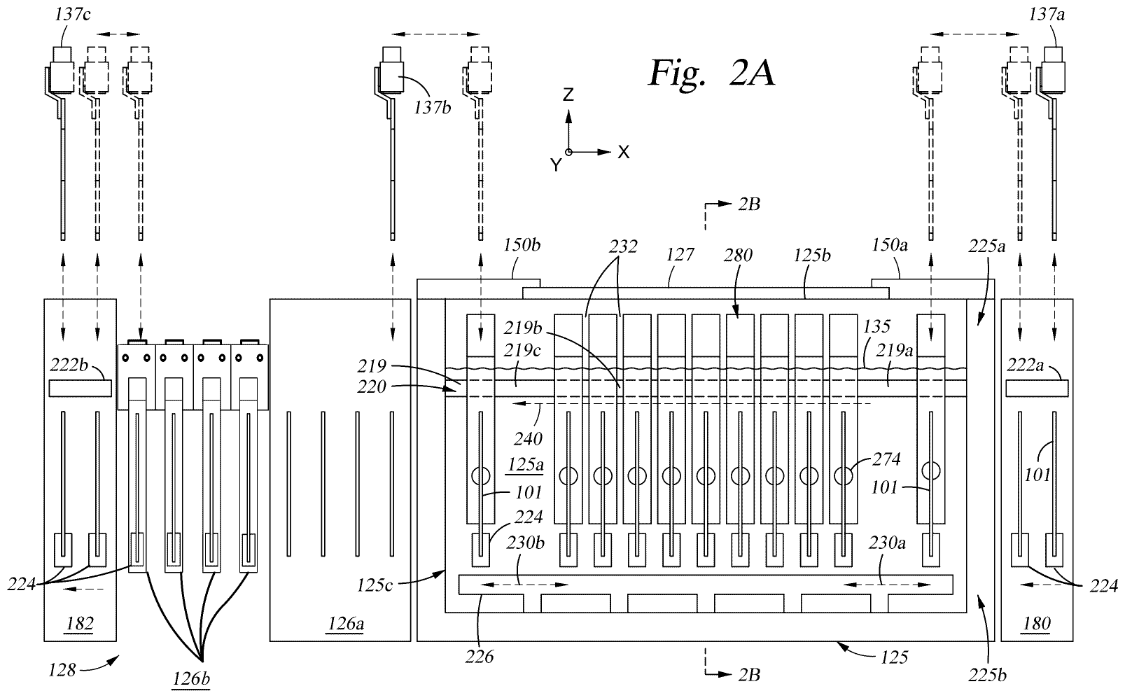

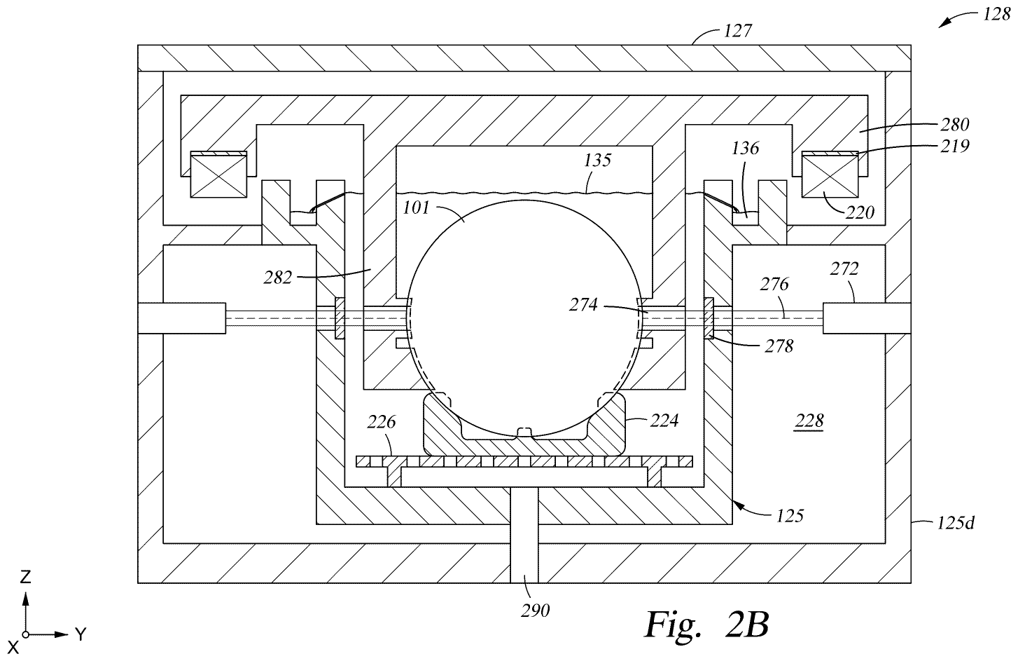

FIG. 2A illustrates a simplified schematic side view of the cleaning unit 128 with some components removed for clarity. The cleaning unit 128 includes the cleaning tank 125 and one or more dedicated robot arm assemblies 137a, 137b, and 137c that are used to transfer the substrates 101 within the cleaning unit 128. The cleaning tank 125 comprises an inner volume 125a defined by a top surface 125b and an outer surface 125c wherein a sulfuric peroxide mixture 135 is contained. The cleaning tank 125 can generally be made from any suitable material, that is not reactive, to be used with a mixture of sulfuric acid and peroxide. In some embodiments of the disclosure, the cleaning tank can be formed from a material selected from the group of PVDF, PTFE, quartz or other useful material.

The cleaning tank 125 may also comprise injectors 290 (FIG. 2B) and perforated dispersion plates 226 at a bottom of the cleaning tank 125 to introduce a laminar flow of chemicals into the cleaning tank 125. For example, one or more of the injectors 290 may introduce a fluid flow of a sulfuric acid and hydrogen peroxide mixture 135 that passes through perforations in the perforated dispersion plates 226, creating a laminar flow of the sulfuric peroxide mixture 135 within the cleaning tank 125. Alternatively, the injectors 290 may introduce an ozone gas through the dispersion plates 226 to create a sulfuric acid and ozone gas mixture within the cleaning tank 125.

The cleaning tank 125 has a stationary lid 127 located at the top surface 125b of the cleaning tank 125. The stationary lid 127 may be hinged and may be opened for maintenance of the cleaning tank 125, but remains stationary during SPM cleaning of substrates. Preferably, the stationary lid 127 covers a majority of the top surface 125b of the cleaning tank 125. The cleaning tank 125 also has an input lid assembly 150a at an entry point in the cleaning tank 125, and an output lid assembly 150b at an exit point in the cleaning tank 125. The input lid assembly 150a and the output lid assembly 150b are disposed on opposing sides of the stationary lid 127. The input lid assembly 150a and the output lid assembly 150b each exposes a portion of an upper end of the cleaning tank 125, and may be actuated independently by the controller 160 (FIGS. 1B/1C). The input lid assembly 150a and the output lid assembly 150b may be hingedly actuated, retractably actuated, or removably actuated by the controller 160. The area of each of the input lid assembly 150a and the output lid assembly 150b is minimized such that, when opened, a minimal area of an inner volume of the cleaning tank 125 is exposed.

Depicted on one side the cleaning tank 125 is the input tank 180 where the second substrate handler 104 (FIG. 1A), controlled by the controller 160, places a substrate 101 to be cleaned into a holder 224. The input tank 180 may have a plurality of holders 224 to hold a plurality of substrates 101 in a queue to be processed in the cleaning tank 125. The input tank 180 may also include an input transport system 222a configured similarly to a walking beam system 220 of the cleaning tank 125 described further in FIG. 2B. For example, the input transport system 222a may include holders 224 and a system of linkages and conveyors (not shown). The input transport system 222a may move a substrate 101 along a queue in the input tank 180 by advancing the substrate 101 to the next available holder 224. Once the substrate 101 reaches the last in a series of holders 224 in the input tank 180, the first transfer robot arm assembly 137a, controlled by the controller 160, grasps the substrate 101 and removes it from the holder 224 and the input tank 180.

The controller 160 actuates the input lid assembly 150a to an open position. For example, the input lid assembly 150a may be hinged and opened via an actuator such as a motor, slidingly retracted via an actuator such as a motor or cylinder, or lifted via an actuator such as a robot arm. The first transfer robot arm assembly 137a then places the substrate 101 through the opened input lid assembly 150a, submerging the substrate 101 into the sulfuric peroxide mixture 135 disposed in the cleaning tank 125 and onto a transport system, e.g., walking beam system 220. The walking beam system 220 is located on an upper portion 225a of the outer surface 125c of the cleaning tank 125. The first transfer robot arm assembly 137a retracts out of the cleaning tank 125, and the input lid assembly 150a closes, sealing the cleaning tank 125.

The walking beam system 220 may be disposed on the upper portion 225a of the tank 125, a lower portion 225b of the tank 125, or a combination thereof. The walking beam system 220 may include a plurality of linkages or conveyor belts 219 on a single or opposing sides of the cleaning tank 125 that are aligned along the transfer direction through the cleaning tank 125 (i.e., −X direction in FIG. 2A). The plurality of conveyor belts 219 may span the total operating length of the cleaning tank 125 to allow the substrates to be transferred through the cleaning tank 125. In using the walking beam system 220, the substrate 101 is placed onto a holder 224 and gripped using a gripper carriage 280. The gripper carriage 280 is on an upper surface of a first belt 219a of the plurality of conveyor belts 219. Each of the plurality of conveyor belts 219 is actuated, for example by a motor, such that the substrate 101 moves along the length of each belt 219, and in the transfer direction through the cleaning tank 125, at a desired speed. The walking beam system 220 is controlled by the controller 160 to operate in sync to transport the substrate 101 across the length of the cleaning tank 125 to a predetermined position under the output lid assembly 150b. The walking beam system 220 is actuated in such a manner as to cause a first isolation gap 230a to form, when the substrate 101 is initially placed into the cleaning tank 125, between an input position and the next nearest substrate 101 previously placed within the cleaning tank 125. Preferably, the first isolation gap 230a is between 10 mm and 150 mm, preferably between 50 mm and 100 mm, preferably between 60 mm and 90 mm, preferably between 70 mm and 80 mm. The first isolation gap 230a (FIG. 2A) may be created by having the speed of the first belt 219a be slower than the speed of a second belt 219b. The substrate 101 then follows a motion path 240, via the walking beam system 220, while being processed. Before reaching the output lid assembly 150b, the walking beam system 220 is actuated to create a second isolation gap 230b by having the speed of a third belt 219c be faster than the speed of the second belt 219b. Preferably, the second isolation gap 230b is between 50 mm and 100 mm, preferably between 60 mm and 90 mm, preferably between 70 mm and 80 mm. The output lid assembly 150b is actuated by the controller 160 into an open position similar to the input lid assembly 150a. Once the substrate 101 moves across the second isolation gap 230b, a second transfer robot arm assembly 137b, controlled by the controller 160, lifts the substrate 101 out of the sulfuric peroxide mixture 135 and out of the cleaning tank 125 through the opened output lid assembly 150b. Once the substrate 101 is out of the cleaning tank 125, the output lid assembly 150b is actuated into a closed position by the controller 160 in a similar manner to the input lid assembly 150a, sealing the cleaning tank 125.

The second transfer robot arm assembly 137b, controlled by the controller 160, then places the substrate 101 into the soak tank 126a for processing. The soak tank 126a may be configured for post-SPM grouped soaks where a group of substrates 101, for example four, may be immersed in a hot soak bath. The hot soak bath can include a warm liquid that is disposed in the soak tank 126a, which allows the substrate 101 to cool after being processed in the SPM solution found in the cleaning tank 125. The warm rinsing liquid may be at a temperature between the temperature of the sulfuric peroxide mixture and room temperature, preferably between 20° C. and 150° C., preferably between 40° C. and 130° C., preferably between 60° C. and 80° C. This cooling allows for the substrate 101 to be subsequently rinsed in the plurality of rinse tanks 126b with a reduced risk of the substrate cracking due to thermal shock. The rinsing liquid can include DI water and/or one or more rinsing agents. The rinsing liquid within the soak tank 126a can be circulated during operation to remove SPM solution from the substrates when placed in the soak tank 126a.

After a predetermined period of time in the soak tank 126a, the third transfer robot arm assembly 137c transfers a substrate 101 between the soak tank 126a and one of the rinse tanks 126b. Each of the plurality of rinse tanks 126b is configured to hold a single substrate 101. As the soak tank 126a may be configured to hold a group of substrates 101, the plurality of rinse tanks 126b may include a matching number of rinse tanks, for example four rinse tanks 126b. Matching the number of rinse tanks 126b to the number of substrates 101 grouped in the soak tank 126a provides an available rinse tank 126b for a substrate 101 that has completed its soak in the soak tank 126a. In some embodiments, it is desirable to assure that the rinsing process performed in the rinse tank 126b is shorter than the soak time in the soak tank 126a. This allows for optimum throughput as each substrate 101 does not need to be held unnecessarily in the soak tank 126a Each of the rinse tanks 126b is equipped to hot rinse any remaining SPM solution residue, such as H₂SO₄ residue, without shocking the substrate after SPM cleaning plus a cold de-ionized water rinse to cool the substrate to room temperature. This rinsing step also further cleans residue from the substrate 101.

When the substrate 101 has been processed through the rinse tank 126b, the third transfer robot arm assembly 137c transfers the substrate 101 out of a rinse tank 126b and into an output tank 182. Like the input tank 180, the output tank 182 may have an output transport system 222b configured similarly to the walking beam system 220 of the cleaning tank 125. The output transport system 222b of the output shuttle may advance the cleaned substrate 101 through the output tank 182 by placing it onto the next available holder 224 in the output tank 182. Once the substrate 101 reaches the last in a series of holders 224 in the output tank 182, the cleaned substrate 101 is transferred out for further processing in the CMP processing system 100. Thus, in some embodiments, after the components in the second cleaning unit 128 sequentially processes the substrate, the second substrate handler 104 transfers the substrate 101 to the first cleaning unit 124 for processing before transferring the substrate 101 to the factory interface 102. In some embodiments, the cleaning process sequence performed in the first cleaning unit 124 can include performing a horizontal pre-cleaning process in the first cleaning module 107, performing a cleaning process in the second cleaning module 109, and then a rinsing and drying process in the a third cleaning module 110. The substrate handler 103 is used to then return the substrate to its respective loading station 102A.

The system described in FIG. 2A allows substrates to be processed individually and in batches. The cleaning tank 125 may be configured to process multiple substrates 101 at once, e.g., in batches, of a desired quantity of substrates, such as about 50, about 30, or about 20. Processing substrates in a batch mode achieves benefits to efficiency and materials usage for a number of substrates. Performing the cleaning or rinsing on substrates individually allows each substrate to be processed for a time directed by the controller 160 in the cleaning unit 128, which can be longer than the time in other system modules, without impacting the overall throughput of the CMP processing system 100 and allowing single substrate processing in other portions of the CMP processing system 100.

FIG. 2B illustrates a schematic front view of the cleaning tank 125 of the cleaning unit 128, shown from the perspective of section line B-B in FIG. 2A. The cleaning tank 125 may be configured to contain the sulfuric peroxide mixture 135 for substrate cleaning. Due to the amount of heat produced by the sulfuric peroxide mixture 135 during substrate cleaning, the cleaning tank 125 may be enclosed in a secondary holding tank 125d with insulation 228 disposed between the secondary holding tank 125d and the cleaning tank 125. The secondary holding tank 125d and the insulation 228 prevent excessive levels of heat from escaping the cleaning tank 125 and damaging nearby components, e.g., the transfer robot arm assembly assemblies 137a, 137b, and 137c.

The cleaning tank 125 has at least one overflow weir 136 that comprises a scalloped edge or V-shaped notches. The at least one overflow weir 136 allows overflowing sulfuric peroxide mixture 135 to exit the cleaning tank 125 where the overflowing sulfuric peroxide mixture 135 may be collected for disposal or recirculation.

As shown in FIG. 2B, the substrate 101 is disposed in the cleaning tank 125 and may move through the cleaning tank 125 using the walking beam system 220. The walking beam system may include the use of the gripper carriage 280 that grips the substrate 101 using grippers 282. The holder 224 can be an incorporated feature on the perforated dispersion plate 226 and may project away orthogonally to allow space for grippers 282 when used. The grippers 282 may also comprise at least one component 274 of a presence sensor through-beam system 272 configured to detect the location of the substrate 101 within the cleaning tank 125 using a beam 276. The at least one component 274 may be a window or an opening configured to allow the beam 276 of the presence sensor system 272 to pass. Similarly, the cleaning tank 125 may also include windows 278 configured to allows the beam 276 to pass through. The gripper carriage 280 is configured to interact with the walking beam system 220. For example, the gripper carriage may contact at least one belt 219 of the walking beam system 220.

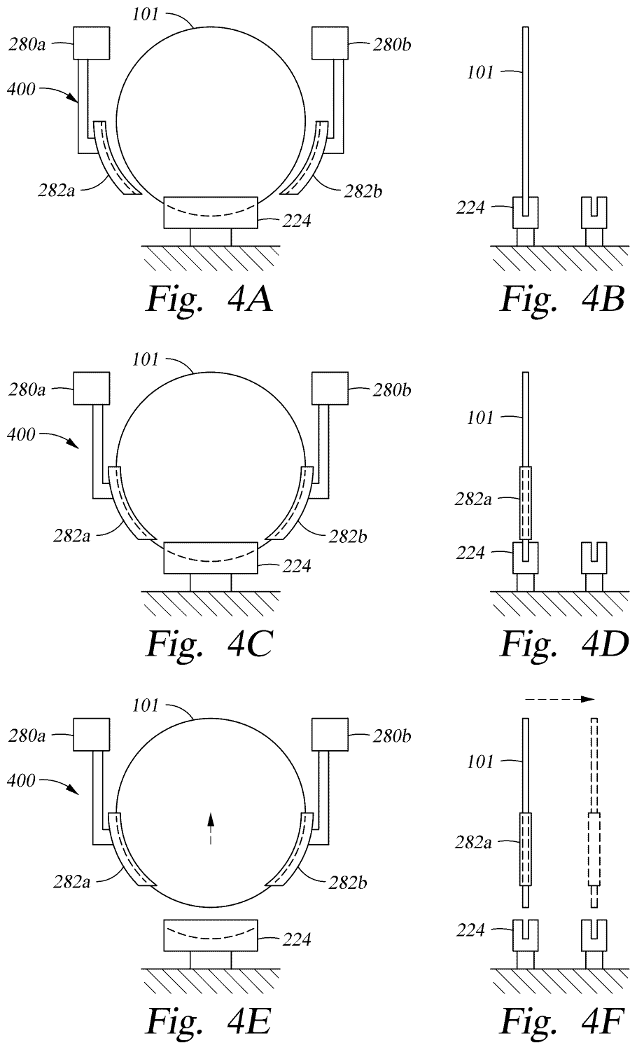

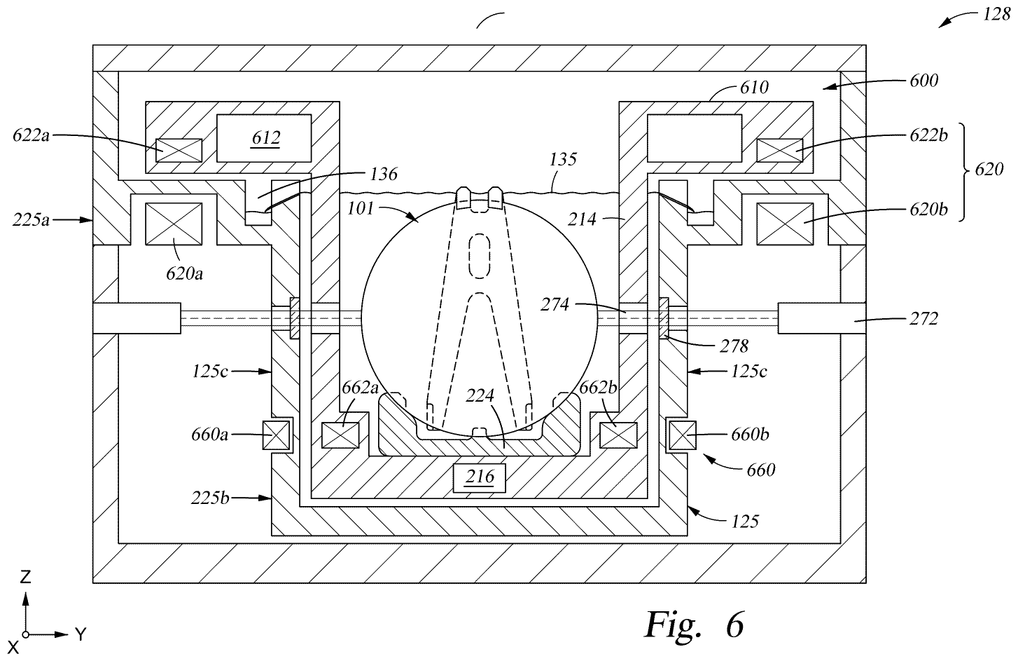

Alternative methods to the conveyor system described in FIGS. 2A and 2B in which substrates 101 are transported through the cleaning tank 125 may use the various in-tank transport systems described herein, e.g., a walking beam transport system 400 of FIGS. 4A-4F or an electromagnetic coil levitation track system of FIG. 6.

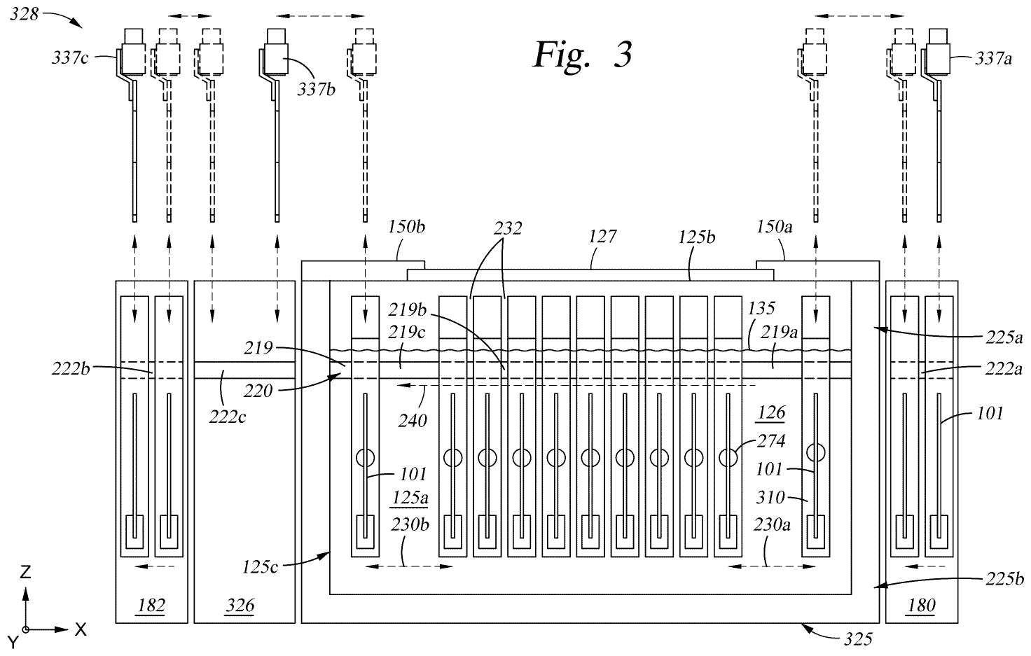

FIG. 3 illustrates a schematic side view of a cleaning unit 328, similar to the cleaning unit 128, but adapted for transporting the substrates 101 in a substrate carrier 310, according to one embodiment. The cleaning unit 328 includes the cleaning tank 325 and one or more dedicated carrier transfer robot arm assembly assemblies 337a, 337b, and 337c to transfer the substrates within the cleaning unit 128. The cleaning tank 325 comprises the inner volume 125a defined by the top surface 125b and the outer surface 125c wherein a sulfuric peroxide mixture 135 is contained. The cleaning tank 325 can generally be made from any suitable material, that is not reactive, to be used with a mixture of sulfuric acid and peroxide.

The cleaning tank 325 may also comprise injectors or dispersion plates (not shown) at a bottom of the cleaning tank 325 to introduce a laminar flow of chemicals into the cleaning tank 325. The cleaning tank 325 has the stationary lid 127 located at the top surface 125b of the cleaning tank 325. The stationary lid 127 may be hinged and may be opened for maintenance of the cleaning tank 325, but remains stationary during SPM cleaning of substrates. Preferably, the stationary lid 127 covers a majority of the top surface 125b of the cleaning tank 325. The cleaning tank 325 also has an input lid assembly 150a at an entry point in the cleaning tank 325, and an output lid assembly 150b at an exit point in the cleaning tank 325. The input lid assembly 150a and the output lid assembly 150b are disposed on opposing sides of the stationary lid 127. The input lid assembly 150a and the output lid assembly 150b each exposes a portion of an upper end of the cleaning tank 325, and may be actuated independently by the controller 160 (FIGS. 1B/1C). The input lid assembly 150a and the output lid assembly 150b may be hingedly actuated, retractably actuated, or removably actuated by the controller 160. The area of each of the input lid assembly 150a and the output lid assembly 150b is minimized such that, when opened, a minimal area of an inner volume of the cleaning tank 325 is exposed.

Depicted on one side of the cleaning tank 325 is the input tank 180 where the second substrate handler 104, controlled by the controller 160, places a substrate 101 to be cleaned into the substrate carrier 310. A first carrier transfer robot arm assembly 337a, controlled by the controller 160, then grasps the substrate carrier 310 containing the substrate 101 and removes it from the input tank 180.

The controller 160 actuates the input lid assembly 150a to an open position. For example, the input lid assembly 150a may be hinged and opened via an actuator such as a motor, slidingly retracted via an actuator such as a motor or cylinder, or lifted via an actuator such as a robot arm. The first carrier transfer robot arm assembly 337a then places the substrate carrier 310 through the opened input lid assembly 150a, submerging the substrate carrier 310 into the sulfuric peroxide mixture 135 disposed in the cleaning tank 325 and onto a transport system, e.g., walking beam system 220. The walking beam system 220 is located on the upper portion 225a of the outer surface 125c of the cleaning tank 325. The first carrier transfer robot arm assembly 337a retracts out of the cleaning tank 325, and the input lid assembly 150a closes, sealing the cleaning tank 325.

The walking beam system 220 may include a pair of continuous conveyor belts or linkages on a single or opposing sides of the cleaning tank 325 whose operating length spans the length of the cleaning tank 325. The continuous belts may each be a plurality of separate belts, such as three, whose total operating length spans the length of the cleaning tank 325. The substrate carrier 310 is placed onto an upper surface of each belt 219. Each belt 219 is actuated, for example by a motor, such that the substrate carrier 310 moves along the length of the belt 219 at a desired speed. The walking beam system 220 is controlled by the controller 160 to operate in sync to transport the substrate carrier 310 across the length of the cleaning tank 325 to a predetermined position under the output lid assembly 150b. The walking beam system 220 is actuated in such a manner as to cause a first isolation gap 230a from when the substrate carrier 310 is initially placed into the cleaning tank 325 and other substrates already being processed within the cleaning tank 325. The first isolation gap 230a may be created by an initial pause at the beginning of the walking beam system 220 and then an increase in speed to match a predetermined gap 232 between other substrates. Preferably, the substrate carrier 310 reaches the predetermined gap 232 while under the stationary lid 127. The walking beam system 220 may comprise multiple belts, such as three, where each belt has its own speed control. The walking beam system 220 may be disposed on the upper portion 225a of the cleaning tank 325, the lower portion 225b of the cleaning tank 325, or a combination thereof. The substrate carrier 310 then follows a motion path 240, via the walking beam system 220 while being processed. Before reaching the output lid assembly 150b, the walking beam system 220 is actuated to create the second isolation gap 230b in a similar manner to which the walking beam system 220 created the first isolation gap 230a. The output lid assembly 150b is actuated by the controller 160 into an open position similar to the input lid assembly 150a. Once the substrate carrier 310 moves across the second isolation gap 230b, a second carrier transfer robot arm assembly 337b, controlled by the controller 160, lifts the substrate carrier 310 out of the sulfuric peroxide mixture 135 and out of the cleaning tank 325 through the opened output lid assembly 150b. Once the substrate carrier 310 is out of the cleaning tank 325, the output lid assembly 150b is actuated into a closed position by the controller 160 in a similar manner to the input lid assembly 150a, sealing the cleaning tank 325.

The second carrier transfer robot arm assembly 337b, controlled by the controller 160, then places the substrate carrier 310 into the hot/cold rinse tank 326 for processing. The hot/cold rinse tank 326 may also be configured similarly to the cleaning tank 325 and includes a secondary transport system 222c. The secondary transport system 222c may be configured similarly to the transport system 220 of the cleaning tank 325. For example, the secondary transport system 222c may include a conveyor or link system (not shown) configured to transport the substrate carrier 310 through the hot/cold rinse tank 326. The hot/cold rinse tank 326 is equipped for hot rinsing of sulfuric residues without shocking the substrate after SPM cleaning plus a cold de-ionized water rinse to cool the substrate to room temperature. This rinsing also cleans residue from the substrate carrier 310. When the substrate has been processed through the hot/cold rinse tank 326, the third carrier transfer robot arm assembly 337c transfers the substrate carrier 310 into an output tank 182. The cleaned substrate 101 is removed from the substrate carrier 310 and transferred out for further processing in the CMP processing system 100 by the second substrate handler 104 controlled via the controller 160. The substrate carrier 310 is then transferred back to the input tank 180 to receive another substrate via the first or second carrier transfer robot arm assembly assemblies 337a, 337b, 337c.

The system described in FIG. 3 allows substrates to be processed individually and in batches. The cleaning tank 325 may be configured to process multiple substrates in multiple substrate carriers 310 at once, e.g., in batches, of a desired quantity of substrates, such as about 50, about 30, about 20, or about 10, or about 5 wherein there is one substrate 101 in each substrate carrier 310. Processing substrates in a batch mode achieves benefits to efficiency and materials usage for a number of substrates. Performing the cleaning or rinsing on substrates individually allows each substrate to be processed for a time directed by the controller 160 in the cleaning unit 128, which can be longer than the time in other system modules, without impacting the overall throughput of the CMP processing system 100 and allowing single substrate processing in other portions of the CMP processing system 100.

FIGS. 4A-4F depict details of a walking beam transport system 400 which the cleaning tank 125 of the cleaning unit 128 may use to control the movements of the substrates 101, e.g., advance the substrates 101 through a queue. FIG. 4A depicts a walking beam transport system 400 having a plurality of beams, for example beams 280a and 280b, and at least two grippers, e.g., grippers 282a and 282b. The beams 280a, 280b extend longitudinally along the top of the cleaning tank 125. The grippers 282a, 282b extend downward from the beams 280a, 280b, aligning along opposite edges of the substrate 101. FIG. 4B shows an edge view from the left of FIG. 4A of the substrate 101 in the holder 224 with the beams 280a,b and grippers 282a,b removed for clarity.

Upon a signal from the controller 160 (FIGS. 1B and 1C), as shown in FIG. 4C, the grippers 282a and 282b can be actuated to move toward the substrate 101 thereby contacting or gripping the edges of the substrate 101 on opposing sides of the substrate 101. FIG. 4D shows the edge view of the substrate 101 in the holder 224 being contacted with the left gripper 282a with the beams 280a, 280b removed for clarity.

As shown in FIG. 4E, the grippers 282a, 282b retract upward after gripping the substrate 101, thereby lifting the substrate 101 from the holder 224 to a height at which the bottom edge of the substrate 101 is above the upper edge of the holder 224 while still below the upper surface of the sulfuric acid and hydrogen peroxide mixture 135 such that the substrate 101 remains submerged within the sulfuric acid and hydrogen peroxide mixture 135 during transport on the walking beam transport system 400. The grippers 282a, 282b then move axially along the running beams 280a, 280b to transfer the substrate 101 to the next ordinal support, as shown in FIG. 4F with the beams 280a,b removed for clarity. The walking beam transport system 400 moves the substrate 101 nearest the exit of the cleaning tank 125 or the hot/cold rinse tank 126 to the next ordinal holder 224, and works to move consecutive substrates 101 toward the exit of the tank.

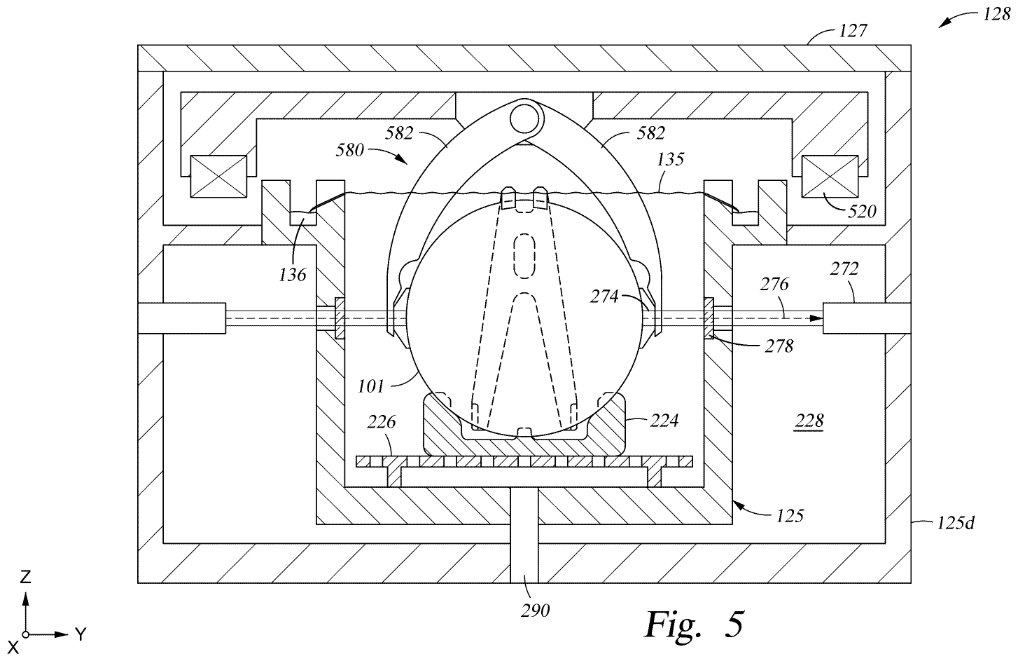

FIG. 5 illustrates a schematic front view of the cleaning tank 125 of the cleaning unit 128, similar to the cleaning unit 128 shown in FIG. 2B, except incorporating a running beam system 520 for moving the substrate. Whereas the walking beam system 220 moves the totality of substrates 101 in a cleaning tank 125, input tank 180, or output tank 182 simultaneously, the running beam system 520 moves the substrates 101 individually. The cleaning tank 125 has at least one overflow weir 136 that comprises a scalloped edge or V-shaped notches. The at least one overflow weir 136 allows overflowing sulfuric acid and hydrogen peroxide mixture 135 to exit the cleaning tank 125 where the overflowing sulfuric acid and hydrogen peroxide mixture 135 may be collected for disposal or recirculation.

As shown in FIG. 5, the substrate 101 is disposed in the cleaning tank 125 and may be moved through the cleaning tank 125 using the running beam system 520. The running beam system 520 may include the use of a running beam gripper robot 580 that grips the substrate 101 using gripper arms 582. The holder 224 can be an incorporated feature on the perforated dispersion plate 226 similar to the holder 224 of FIG. 2B. The running beam gripper robot 580 may also comprise at least one component 274 of the presence sensor through-beam system 272 configured to detect the location of the substrate 101 within the cleaning tank 125 using the beam 276. The at least one component 274 may be a window or an opening configured to allow a beam of the presence sensor system 272 to pass. Similar to the walking beam system 220 of FIG. 2B, the substrate 101 on the running beam system 520 may be configured to maintain the predetermined gap 232 between sequential substrates 101. The running beam gripper robot 580 is configured to interact with a conveyor system. For example, the running beam gripper robot 580 may contact at least one belt, e.g., belt 519, of the conveyor system, e.g., the running beam system 520.

FIG. 6 is a schematic front view of a cleaning unit 128, similar to the cleaning unit 128 of FIG. 2B, except the cleaning unit 128 in FIG. 6 includes a substrate carrier 610 and an electromagnetic (EM) coil levitation track system 600 which can be used to move the substrates 101 on substrate carriers 610 through the cleaning tank 125 (or the hot/cold rinse tank 126) of the cleaning unit 128. The substrate carriers 610 are similar to the substrate carriers 310 described above with respect to FIG. 3 with additional features as described below. The EM coil levitation track system 600 may include an upper levitation track system 620 disposed on the upper portion 225a of the cleaning tank 125, a lower levitation track system 660 disposed on the lower portion 225b of the cleaning tank 125, or a combination thereof. The upper levitation track system 620 may include a first upper levitation track 620a, a second upper levitation track 620b, a first upper magnet 622a, and a second upper magnet 622b. The lower levitation track system 660 may include a first lower levitation track 660a, a second lower levitation track 660b, a first lower magnet 662a, and a second lower magnet 662b.

The upper magnets 622a, 622b may be any suitable superconductive magnet such as an aluminum nickel cobalt (AlNiCo) magnet. The upper magnets 622a, 622b may be disposed or embedded within each lift handle feature 612 of the substrate carrier 610. The upper magnets 622a, 622b are polarized such as to cause an opposing magnetic force against the upper levitation tracks 620a, 620b and lift the substrate carrier 610 upward. The upper levitation tracks 620a, 620b contain coils. The controller 160 (FIGS. 1B and 1C) induces an electric current within the coils of the upper levitation tracks 620a, 620b causing the coils to act as electromagnets temporarily. The like poles of the upper magnets 622a, 622b and the coil of upper levitation tracks 620a and 620b repel and push the substrate carrier 610 upward. Successive like poles on the upper levitation tracks 620a and 620b are successively energized by the controller 160 to push the substrate carrier 610 forward through the cleaning tank 125 and/or hot/cold rinse tank 126.

Similarly, the lower magnets 662a, 662b may be any suitable superconductive magnet such as an AlNiCo magnet. The lower magnets 662a, 662b are shown disposed within opposing bottom corners of the substrate carrier 610, but may be disposed on any opposing surfaces of the substrate carrier 610. The lower magnets 662a, 662b are polarized such as to cause an opposing magnetic force against the lower levitation tracks 660a, 660b when the lower levitation tracks 660a, 660b are energized by the controller 160. Similar to the upper levitation tracks 620a, 620b, successive like poles on the lower levitation tracks 660a and 660b are successively energized by the controller 160 to push the substrate carrier 610 forward through the cleaning tank 125 and/or the hot/cold rinse tank 126.

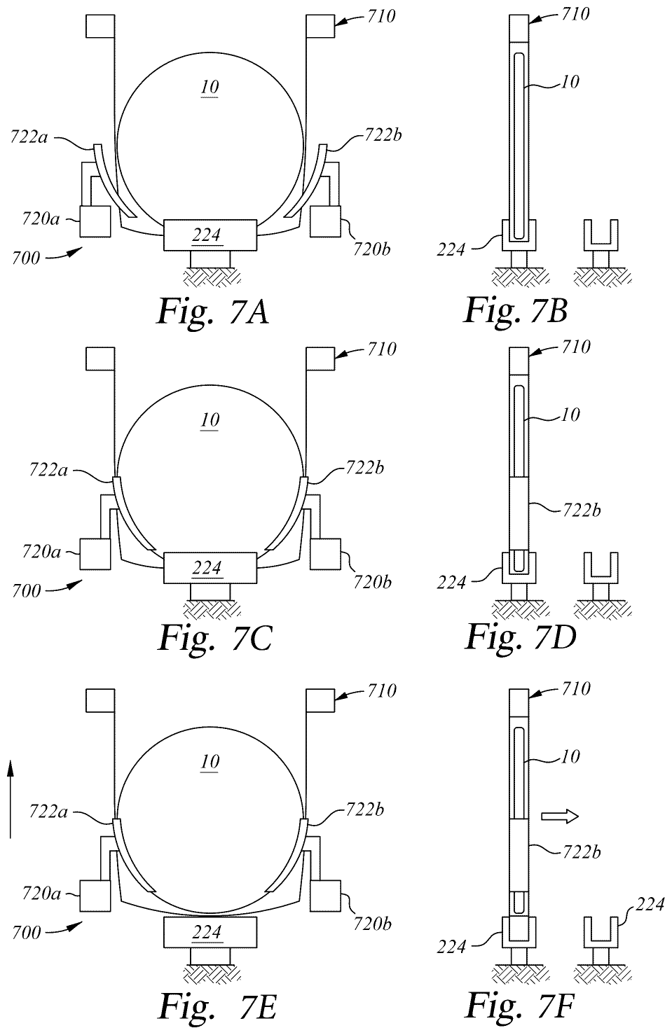

FIGS. 7A-7F are schematic diagrams depicting a walking beam system 700 and the operation thereof. As shown in FIG. 7A, a substrate carrier 710 is positioned vertically in a holder 224 within the cleaning tank 125 or the hot/cold rinse tank 126. FIG. 7B shows an edge view from the left of FIG. 7A of the substrate carrier 710 in the holder 224. The walking beam is not shown for clarity. Referring again to FIG. 7A, adjacent the substrate carrier 710 on opposing sides are two walking beam rails 720a and 720b. Coupled to each walking beam rail, 720a and 720b, is a gripper, 722a and 722b, respectively. The grippers 722a, 722b can be arranged to be opposite one another and in line with the substrate carrier 710.

Upon a signal from the controller 160 (FIGS. 1A and 1B), as shown in FIG. 7C, the grippers 722a and 722b can be actuated to move toward the substrate carrier 710, thereby contacting the edges of the substrate carrier 710 on opposing sides of the substrate carrier 710. FIG. 7D shows the edge view of the substrate carrier 710 in the holder 224 being contacted with the left gripper 722a.

As shown in FIG. 7E, the walking beam system 700 then raises the grippers 722a, 722b, thereby lifting the substrate carrier 710 from the holder 224 to a height at which the bottom edge of the substrate carrier 710 is above the upper edge of the holder 224 while still below the upper surface of the sulfuric acid and hydrogen peroxide mixture 135 such that the substrate carrier 710 remains submerged within the sulfuric acid and hydrogen peroxide mixture 135 during transport on the walking beam transport system 700. Alternatively, the holders 224 could be lowered so that the substrate is placed into the grippers 722a, 722b. The grippers 722a, 722b then move axially along the walking beams 720 to transfer the substrate carrier 710 to the next ordinal holder 224n, as shown in FIG. 7F. When operating within the cleaning tank 125 and the hot/cold rinse tank 126, the grippers 722a, 722b operate in concert to transfer the substrate carriers 710 in the tanks simultaneously to the next ordinal holder 224.

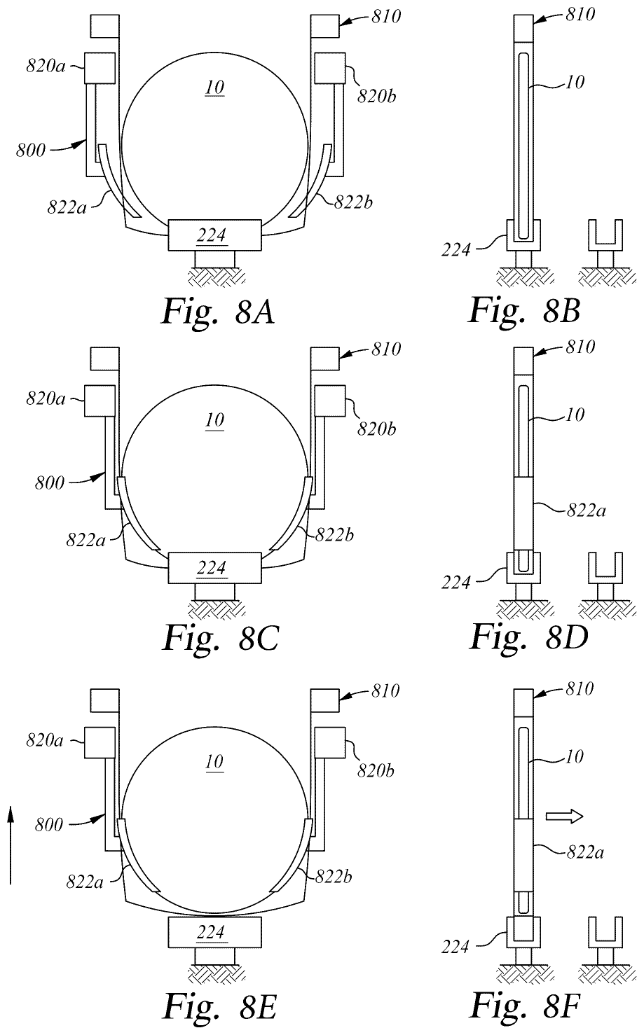

Alternatively, FIGS. 8A-8F depict details of a running beam system 800 which the cleaning tank 125 and the hot/cold rinse tank 126 of the second cleaning unit 128 can use to control the movements of the substrate carriers 810. FIG. 8A depicts a running beam system 800 wherein the beams 820a, 820b extend longitudinally along the top of the tank. The grippers 822a, 822b extend downward from the beams 820a, 820b, aligning along opposite edges of the substrate carrier 810. FIG. 8B shows an edge view from the left of FIG. 8A of the substrate carrier 810 in the holder 224. The running beam is not shown for clarity. Referring again to FIG. 8A, the running beam system 800 includes the same components as the walking beam 700 system, including beams 820a, 820b and grippers 822a, 822b.

Upon a signal from the controller 160 (FIGS. 1A and 1B), as shown in FIG. 8C, the grippers 822a and 822b can be actuated to move toward the substrate carrier 810 thereby contacting the edges of the substrate carrier 810 on opposing sides of the substrate carrier 810. FIG. 8D shows the edge view of the substrate carrier 810 in the holder 224 being contacted with the left gripper 822a.

As shown in FIG. 8E, the grippers 822a, 822b retract upward after gripping the substrate carrier 810, thereby lifting the substrate carrier 810 from the holder 224 to a height at which the bottom edge of the substrate carrier 810 is above the upper edge of the holder 224 while still below the upper surface of the sulfuric acid and hydrogen peroxide mixture 135 such that the substrate carrier 810 remains submerged within the sulfuric acid and hydrogen peroxide mixture 135 during transport on the running beam system 800. The grippers 822a, 822b then move axially along the running beams 820a, 820b to transfer the substrate carrier 810 to the next ordinal support, as shown in FIG. 8F. Whereas the walking beam system 700 moves the totality of substrate carriers 810 in a cleaning tank 125 or a hot/cold rinse tank 126 simultaneously, the running beam system 800 moves the substrate carriers 810 individually. The running beam system 800 moves the substrate carrier 810 nearest the exit of the cleaning tank 125 or the hot/cold rinse tank 126 to the next ordinal holder 224, and works to move consecutive substrate carriers 810 toward the exit of the tank.

The present disclosure provides a technical solution to the problems described above by providing a CMP cleaning system that includes a cleaning unit with an SPM cleaning tank, input and output tanks, and at least one hot/cold rinse tank configuration. Specifically, the SPM cleaning tank is described that has as lid assembly, dedicated transfer robot arm assembly assemblies, a transport system such as a walking beam transport system, and a substrate queue that allows for substrates to be processed in batch mode and individually through the entire cleaning unit. Doing so improves the throughput of the cleaning unit while preserving the chemistry of the SPM cleaning tank and protecting the CMP cleaning system components from unnecessary exposure to the sulfuric peroxide mixture.

When introducing elements of the present disclosure or exemplary aspects or embodiment(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to embodiments of the present disclosure, other and further embodiments of the disclosure may be devised without departing from the basic scope thereof, and the scope thereof is determined by the claims that follow.

What is claimed is:

1. A system for cleaning a substrate, the system comprising:
an input tank having an input tank opening that is configured to receive a substrate oriented in a vertical orientation;
a cleaning tank oriented substantially parallel to the input tank, the cleaning tank comprising:
a stationary lid;
at least one input lid assembly adjacent to a first side of the stationary lid configured to open to an input side of the cleaning tank;
at least one output lid assembly adjacent to a second side of the stationary lid configured to open to an output side of the cleaning tank, wherein the stationary lid, input lid assembly, and the output lid assembly covers a top surface of the cleaning tank; and
a transport system configured to transport the substrate from the input side of the cleaning tank to the output side of the cleaning tank;
a soak tank comprising an opening adjacent to the output side of the cleaning tank and configured to hold a plurality of substrates;
a plurality of rinse tanks adjacent to the soak tank, each of the plurality of rinse tanks configured to hold a single substrate;
an output tank adjacent to the plurality of rinse tanks, the output tank having a transport system to advance a substrate through the output tank; and
a plurality of transfer robot arms configured to transfer the substrate between the input tank, the cleaning tank, the soak tank, the plurality of rinse tanks, and the output tank.

2. The system of claim 1, further comprising:
a polishing station;
a cleaning unit comprising at least one horizontal pre-clean module, at least one vertical cleaning module, and at least one drying module; and
a substrate handler configured to transport a substrate between the polishing station, the cleaning unit, the input tank, and the output tank.

3. The system of claim 1, wherein the cleaning tank further comprises:
a presence sensor through-beam system within the cleaning tank;
a perforated dispersion plate;
a plurality of holders along a bottom of the cleaning tank; and
at least one injector configured to provide a fluid flow into the cleaning tank.

4. The system of claim 1, wherein the transport system is a walking beam system comprising:
a gripper carriage; and
at least two grippers connected to the gripper carriage, the grippers configured to grip edges of the substrate.

5. The system of claim 1, wherein the soak tank is a grouped soak tank and a number of the plurality of rinse tanks matches the number of substrates the grouped soak tank is capable of processing.

6. The system of claim 1, wherein the cleaning tank is configured to contain a substrate cleaning solution, the substrate cleaning solution comprising a sulfuric acid and hydrogen peroxide mixture.

7. The system of claim 1, wherein the cleaning tank is configured to contain a substrate cleaning solution, the substrate cleaning solution comprising a sulfuric acid and ozone mixture.

8. The system of claim 1, wherein the output tank comprises a plurality of holders along a bottom of the output tank configured to hold the substrate in a queue.

9. A system for cleaning a substrate, the system comprising:
an input tank;
a cleaning tank configured to contain a cleaning solution for applying to the substrate, the cleaning tank comprising:
a top surface and an outer surface adjacent to the top surface, the top surface and the outer surface defining an inner volume, the outer surface comprising:
an upper portion, and
a lower portion;
a first transport system connected to the upper portion of the cleaning tank, the lower portion of the cleaning tank, or a combination thereof, the first transport system configured to transport a substrate carrier containing the substrate;
a stationary lid covering a majority of the top surface of the cleaning tank;
at least one input lid assembly adjacent to a first side of the stationary lid; and
at least one output lid assembly adjacent to a second side of the stationary lid, wherein the at least one input lid assembly, the stationary lid, and the at least one output lid assembly cover an entirety of the top surface;
a rinse tank, wherein the rinse tank includes a second transport system configured to transport the substrate carrier containing the substrate through the rinse tank;
an output tank; and
a robot system comprising a plurality of robot arms configured to transfer the substrate carrier between the input tank, the cleaning tank, the rinse tank, and the output tank.

10. The system of claim 9, wherein the substrate carrier comprises:
at least one lift handle feature incorporated in an upper portion of the substrate carrier; and
a substrate holder at a bottom inner surface of the substrate carrier configured to hold the substrate.

11. The system of claim 10, wherein the first transport system is a conveyor system, a walking beam system, a running beam system, or an electromagnetic coil levitation track system.

12. The system of claim 10, wherein the first transport system is a conveyor system comprising a plurality of belts or linkages on opposing sides of the cleaning tank, wherein the plurality of belts or linkages are actuated to cause a first isolation gap and a second isolation gap.

13. The system of claim 10, wherein the first transport system is an electromagnetic coil levitation track system comprising an upper track system and a lower track system, wherein the upper track system and the lower track system each comprises a coil spanning a length of the cleaning tank, wherein the coil is configured to repel a magnet in the substrate carrier using an electromagnetic force when energized.

14. The system of claim 10, wherein the input lid assembly is configured to be actuated to allow a first portion of the top surface to be exposed such that the robot system transporting the substrate carrier may access the inner volume of the cleaning tank and wherein the output lid assembly is configured to be actuated to allow a second portion of the top surface to be exposed such that the robot system may access the substrate carrier within the inner volume of the cleaning tank.

15. A system for cleaning a substrate, the system comprising:
a polishing station;
a cleaning unit comprising at least one horizontal pre-clean module, at least one vertical cleaning module, and at least one drying module;
an input tank;
a cleaning tank comprising:
a stationary lid;
at least one input lid assembly adjacent to a first side of the stationary lid configured to open to an input side of the cleaning tank;
at least one output lid assembly adjacent to a second side of the stationary lid configured to open to an output side of the cleaning tank, wherein the stationary lid, input lid assembly, and the output lid assembly covers a top surface of the cleaning tank; and
a transport system configured to transport the substrate from the input side of the cleaning tank to the output side of the cleaning tank;
a soak tank;
a plurality of rinse tanks;
an output tank;
a substrate handler configured to transport a substrate between the polishing station, the cleaning unit, the input tank, and the output tank;
a first transfer robot arm assembly, a second transfer robot arm assembly, and a third transfer robot arm assembly configured to transfer the substrate between the input tank, the cleaning tank, the soak tank, the plurality of rinse tanks, and the output tank; and
a controller comprising a memory and processor, the controller configured to:
insert the substrate into the cleaning tank using the first transfer robot arm;
transport the substrate through a queue along the cleaning tank using the transport system; and
removing the substrate from the cleaning tank using the second transfer robot arm assembly after the substrate reaches an end of the queue.

16. The system of claim 15, the controller further configured to:
transfer the substrate to the cleaning unit after polishing the substrate in the polishing station using the substrate handler; and
transfer the substrate using the substrate handler from the cleaning unit to the input tank after processing.

17. The system of claim 15, wherein the transport system transports the substrate through the queue while:
maintaining a first isolation gap at a beginning of the queue, the first isolation gap being between 50 mm and 100 mm; and
maintaining a second isolation gap at an end of the queue, the second isolation gap being between 10 mm and 150 mm.

18. The system of claim 15, wherein the controller is further configured to:
insert the substrate into the input tank using a substrate handler before inserting the substrate into the cleaning tank, the input tank comprising:
a plurality of holders along a bottom of the input tank configured to hold the substrate in an input queue; and
an input transport system configured to advance the substrate through the input queue; and
after inserting the substrate into the input tank but before inserting the substrate into the cleaning tank, remove the substrate from the input tank using the first transfer robot arm.

19. The system of claim 15, wherein the controller is further configured to:
after removing the substrate from the cleaning tank, insert the substrate into a soak tank using the second transfer robot arm; and
after a predetermined period of time, removing the substrate from the soak tank using the third transfer robot arm assembly and placing the substrate into a rinse tank.

20. The system of claim 15, wherein the controller is further configured to:
insert the substrate into an output tank using the third transfer robot arm assembly, the output tank comprising:
a plurality of holders along a bottom of the output tank configured to hold the substrate in an output queue; and
an output transport system configured to advance the substrate through the output queue;
advance the substrate along the output queue through the output tank; and
remove the substrate at an end of the output queue using a second wet robot arm.
